(19) United States
(12) Patent Application Publication
(10) Pub. No.: US 2022/0157661 A1
(43) Pub. Date: May 19, 2022

(54) EPITAXIAL GROWTH AND TRANSFER VIA PATTERNED TWO-DIMENSIONAL (2D) LAYERS

(71) Applicant: Massachusetts Institute of Technology, Cambridge, MA (US)

(72) Inventors: Jeehwan Kim, Cambridge, MA (US); Sanghoon Bae, Cambridge, MA (US); Yunjo Kim, Cambridge, MA (US)

(73) Assignee: Massachusetts Institute of Technology, Cambridge, MA (US)

(21) Appl. No.: 17/530,870

(22) Filed: Nov. 19, 2021

Related U.S. Application Data
(63) Continuation of application No. 16/763,584, filed on May 13, 2020.
(60) Provisional application No. 62/585,954, filed on Nov. 14, 2017.

(51) Int. Cl. H01L 21/78; C30B 25/04; C30B 25/18; C30B 29/02; H01L 21/02

(52) U.S. Cl. CPC H01L 21/7813; C30B 25/20; C30B 25/186; C30B 29/02; H01L 21/02381; H01L 21/02389; H01L 21/02392; H01L 21/02395; H01L 21/02444; H01L 21/02458; H01L 21/02485; H01L 21/02513; H01L 21/0254; H01L 21/02543; H01L 21/02546; C30B 25/04

(57) ABSTRACT

Embodiments including apparatus, systems, and methods for nanofabrication are provided. In one example, a method of manufacturing a semiconductor device includes forming a two-dimensional (2D) layer comprising a 2D material on a first substrate and forming a plurality of holes in the 2D layer to create a patterned 2D layer. The method also includes forming a single-crystalline film on the patterned 2D layer and transferring the single-crystalline film onto a second substrate.

### RELATED APPLICATIONS

This application is a continuation of U.S. patent application Ser. No. 16/763,584, filed May 13, 2020, and entitled “EPITAXIAL GROWTH AND TRANSFER VIA PATTERNED TWO-DIMENSIONAL (2D) LAYERS,” which is a national stage filing under 35 U.S.C. § 371 of International Patent Application No. PCT/US2018/060945, filed Nov. 14, 2018, and entitled “EPITAXIAL GROWTH AND TRANSFER VIA PATTERNED TWO-DIMENSIONAL (2D) LAYERS,” which claims priority under 35 U.S.C. § 119(e) to U.S. Provisional Application No. 62/585,954, filed Nov. 14, 2017, and entitled “EPITAXIAL GROWTH AND TRANSFER VIA PATTERNED TWO-DIMENSIONAL (2D) LAYERS,” each of which is incorporated herein by reference in its entirety for all purposes.

### TECHNICAL FIELD

Epitaxial growth and transfer via two-dimensional (2D) layers is generally described.

### BACKGROUND

Elemental semiconductors and compound semiconductors are the basis of modern electronics. The semiconductor industry spent about $7.2 billion worldwide on wafers that serve as substrates for microelectronic components. The functionality of semiconductor devices typically lies on the surface of a semiconductor. Therefore, the bulk of the wafer usually does not offer additional benefits for the electronic device. However, it is challenging for conventional semiconductor growth processes, which usually utilize ingot growth, to grow thinner semiconductor wafers due to the mechanical fragility of the material. As a result, semiconductor devices are usually accompanied by a thick wafer body during fabrication.

In addition, in the current semiconductor industry, the wafer is strongly bonded to the semiconductor device with covalent bonding, which makes it challenging to separate the device layer from the wafer without damaging either the device or wafer or both. Therefore, the entire wafer is usually sacrificed during fabrication, thereby increasing the overall cost of the electronics. While germanium or other compound semiconductors are intensively investigated for various electronics, such as light-emitting diodes (LEDs), lasers, photovoltaic cells, and sensors, their commercial applications are limited to specific fields mainly due to the prohibitive cost of the germanium or compound wafer substrate.

To circumvent this challenge, various methods have been developed over the past decade for wafer recycling, such as chemical lift-off, optical lift-off, and laser lift-off. However, even after a decade of development, the aforementioned methods have not been successful in securing adoption for mass production due to their slow release rate of the active layers, low yield, and the need for post-release treatment of the host substrate.

### SUMMARY

Embodiments of the present invention include apparatus, systems, and methods for nanofabrication. In one example, a method of manufacturing a semiconductor device includes forming a two-dimensional (2D) layer comprising a 2D material on a first substrate and forming a plurality of holes in the 2D layer to create a patterned 2D layer. The method also includes forming a single-crystalline film on the patterned 2D layer and transferring the single-crystalline film onto a second substrate.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIGS. 1A-1D illustrate a method of fabricating a semiconductor device using a patterned two-dimensional (2D) layer.

FIGS. 2A-2H illustrate graphene-based layer fabrication and transfer using graphene patterned with holes.

### DETAILED DESCRIPTION

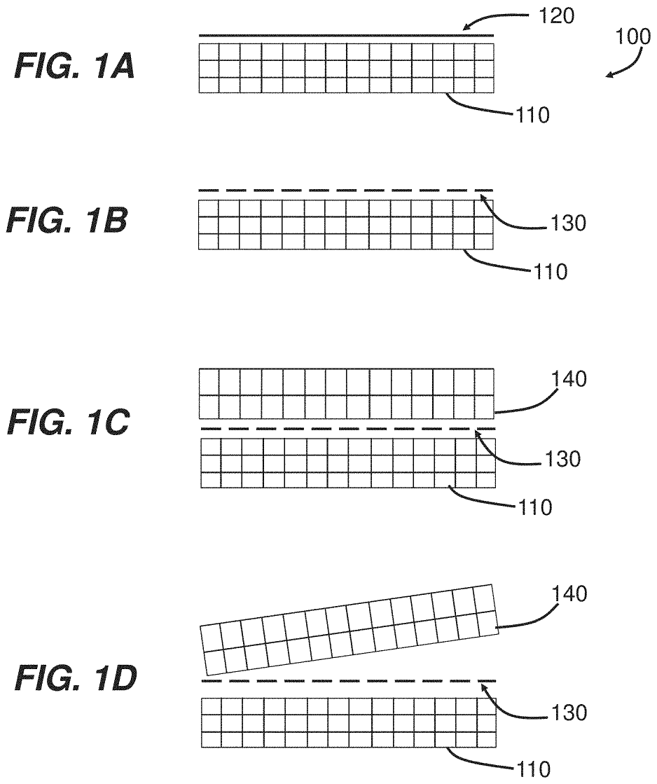

FIGS. 1A-1D illustrate a method 100 of fabricating a semiconductor device using a patterned two-dimensional (2D) layer. In the method 100, a 2D layer 120 is formed on a first substrate 110, as shown in FIG. 1A. In some cases, the first substrate 110 can be prepared by epitaxial growth or pseudomorphic growth on a crystalline substrate (also referred to as a parent substrate). For example, the first substrate 110 can include InGaN grown on GaN. In another example, the first substrate can include InGaP grown on GaAs. In yet another example, the first substrate 110 can include InGaAs grown on InP. In some cases, the first substrate 110 can include silicon, silicon carbide (SiC), germanium, SrTiO₃ (STO), and/or lithium fluoride (LiF), prepared by any appropriate method.

The 2D layer 120 can include any type of 2D material. For example, the 2D layer 120 can include graphene (single crystalline or polycrystalline). In another example, the 2D layer 120 can include a transition metal dichalcogenide (TMD) monolayer, which is an atomically thin semiconductor of the type MX₂, where M is a transition metal atom (e.g., Mo, W, etc.) and X is a chalcogen atom (e.g., S, Se, or Te). For example, the 2D layer 120 can include MoS₂ and WSe₂, among other materials. In yet another example, the 2D layer 120 can include 2D boron nitride (BN). In some embodiments, the 2D material can be arranged as a plurality of atomic layers (e.g., 2, 3, 4, 5, 6, 7, or more atomic layers). For example, in some embodiments, a plurality of graphene layers (e.g., 2, 3, 4, 5, 6, 7, or more graphene layers thick) can be used. In some embodiments, the 2D material is an atomically thin material.

In one example, the 2D layer 120 can be directly grown on the first substrate 110. For example, in some embodiments, graphene can be directly grown on the first substrate 110. In another example, the 2D layer 120 can be grown on another substrate (not shown) and then transferred to the first substrate 110. More details of this layer transfer can be found in PCT Application No. PCT/US2016/050701, filed Sep. 8, 2016, and published as International Patent Application Publication Number WO 2017/044577 on Mar. 16, 2017, entitled “SYSTEMS AND METHODS FOR GRAPHENE BASED LAYER TRANSFER,” which is hereby incorporated by reference in its entirety.

In FIG. 1B, the 2D layer 120 is patterned with a plurality of holes to form a patterned 2D layer 130. In one example, the pattern on the patterned 2D layer 130 can be periodic. In another example, the pattern on the patterned 2D layer 130 can be random (or arbitrary). In some embodiments, at least 50% of a surface of the first substrate 110 on which the patterned 2D layer 130 is located is covered by the 2D material, with the remainder uncovered (e.g., due to holes or other discontinuities in the patterned 2D layer 130). The holes in the pattered 2D layer 130 can be on the nano-scale. For example, the diameter of the holes can be less than 1 μm (e.g., about 1 μm, about 500 nm, about 300 nm, about 200 nm, about 100 nm, about 50 nm, or less, including any values and sub ranges in between).

Various methods can be used to form the patterned 2D layer 130. In one example, a metal mask can be formed on the 2D layer 120. For example, metal deposition can be initiated on the 2D layer 120 to form metal islands and terminated before the metal islands merge with each other, thereby creating a plurality of isolated metal islands (or metal pillars) disposed on the 2D layer 120. These metal islands, collectively, form the metal mask. Then plasma etching can be employed to etch the area of the 2D layer 120 not covered by the metal mask. As another example, metal deposition can be initiated on the 2D layer 120 to form a metal mask comprising a metal layer with holes in the metal mask disposed on the 2D layer 120. Then, plasma etching can be employed to etch the areas of the 2D layer 120 not covered by the metal mask (e.g., through the holes in the metal mask). The plasma can include, for example, oxygen plasma or inert gas plasma (e.g., He plasma or Ar plasma). After the etching of the 2D layer 120, the metal mask can be etched away (e.g., using wet chemical etching), exposing the pattered 2D layer 130 for further processing.

In another example, the patterned 2D layer 130 can be formed using electron beam lithography. In yet another example, the patterned 2D layer 130 can be formed using ion bombardment. In yet another example, the patterned 2D layer 130 can be formed using a noodle shaped metal mask.

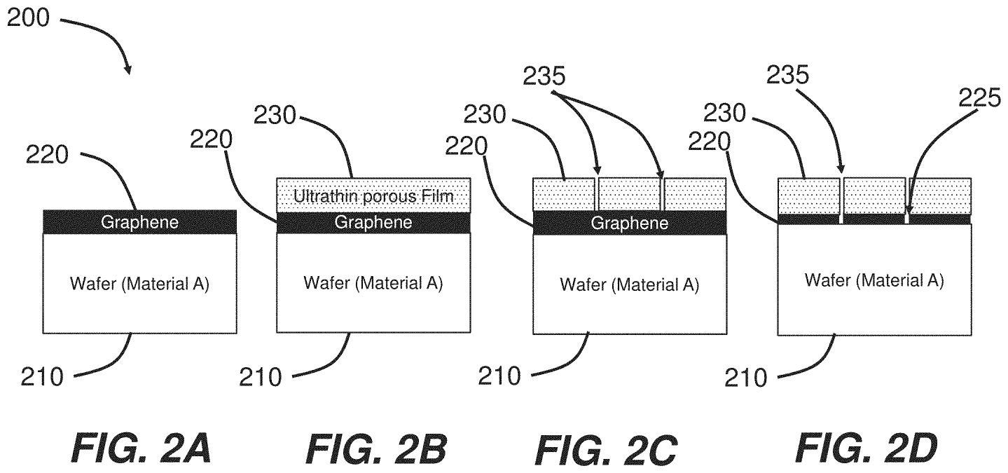

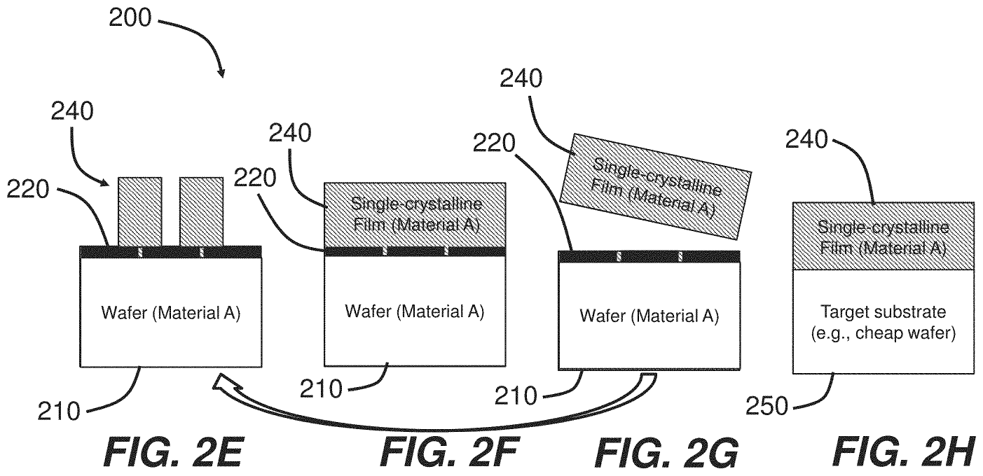

FIG. 1C shows that an epitaxial layer 140 is grown on the patterned 2D layer 130. In this process, an epitaxial seed can be formed through the etched regions (holes) in the patterned 2D layer 130 and then grow laterally over the rest of the patterned 2D layer 130. The majority of bonding at the interface between the epitaxial layer 140 and the first substrate 110 can be van der Waals interaction. In some embodiments, an epitaxial material is grown on the patterned 2D layer (e.g., patterned graphene) for a short enough duration that portions (e.g., islands) of the epitaxial material do not merge with one another and a patterned epitaxial material (e.g., comprising islands) results (e.g., 240 of FIG. 2E). The epitaxial layer 140 can include a single-crystalline material that is substantially identical to the material of the first substrate. The crystalline properties of the epitaxial layer 140 can be substantially the same as the crystalline properties of the first substrate 110.

In FIG. 1D, the epitaxial layer 140 is removed and transferred to a second substrate (not shown in FIGS. 1A-1C) for further processing, leaving the patterned 2D layer 130 on the first substrate 110 for fabricate another epitaxial layer. In this manner, the first substrate 110 and the pattered 2D layer 130 can be used multiple times (e.g., more than 100 times, more than 200 times, more than 300 times, more than 500 times, or more than 1000 times, including any values and sub ranges in between), thereby reducing the average cost of each epitaxial layer 140.

The epitaxial layer 140 can be transferred away using various methods. In one example, a stressor layer can be disposed on the epitaxial layer 140 and a tape layer can be disposed on the stressor layer. For example, the stressor can include a high-stress metal film, such as a Ni film. Using the tape layer and the stressor layer can mechanically exfoliate the epitaxial layer 140 from the 2D pattered layer 130 at a fast release rate by applying high strain energy to the interface between the epitaxial layer 140 and the patterned 2D layer 130.

After the epitaxial layer 140 is disposed on the second substrate, the tape layer and the stressor layer can be removed, leaving the epitaxial layer 140 for further processing, such as forming more sophisticated devices or depositing additional materials on the epitaxial layer 140. For example, the tape layer and the stressor layer can be etched away by a FeCl₃-based solution.

In some cases, the 2D layer 120 can include a combination of multiple sub-layers stitched together. For example, the 2D layer 120 can include multiple sub-layers tiled on the first substrate 110 with adjacent sub-layers are at least partially overlapping so as to substantially cover the entire surface of the first substrate 110.

FIGS. 2A-2H illustrate a method 200 of graphene-based layer fabrication and transfer using graphene patterned with holes (referred to as porous graphene hereafter). The method 200 can be implemented with the graphene functioning as a release layer and the substrate seeding the epitaxial growth of one or more functional layers.

In FIG. 2A, a graphene layer 220 is disposed on a substrate 210. The graphene layer 220 can be grown on the substrate 210 via, for example, chemical vapor deposition. Alternatively, the graphene layer 220 can be transferred to the substrate 210. A porous film 230 (e.g., oxide, nitride, or photoresist film) is then disposed on the graphene layer 220 as shown in FIG. 2B. The porous film 230 has a high density of pinholes (e.g., about one hole per square micron). Alternatively, the porous film 230 can include any film with holes to allow subsequent processing shown in FIGS. 2C-2H.

In FIG. 2C, dry etching using Ar plasma or 02 plasma is carried out to open up the pinholes in the porous film 230. This etching creates a plurality of pinholes 235 in the porous film 230, allowing the ions in the etching plasma to propagate through the porous film 230 to the graphene layer 220. The etching plasma then etches the portion of the graphene layer 220 directly underneath the pinholes 235 in the porous film 230. Ions in the etching plasma can damage the graphene layer 220 by creating a plurality of holes 225 in the graphene layer 220, which now becomes a porous graphene layer 220. In one example, the etching of the porous film 230 and the etching of the graphene layer 220 can be achieved with the same etching plasma. In another example, the etching of the porous film 230 and the etching of the graphene layer 220 can be achieved with different etching plasmas.

In FIG. 2E, the porous film 230 is removed, leaving the now-porous graphene layer 220 exposed for further processing. In one example, the porous film 230 includes photoresist material and can be removed by acetone. In another example, the porous film 230 includes oxide or nitride and can be removed by hydrogen fluoride (HF). FIG. 2E also shows that an epilayer 240 is grown on the porous graphene layer 220. The growth starts from the area where the holes 225 were created. The holes 225 allow direct interaction of the substrate 210 with the epilayer 240, thereby allowing the substrate 210 to guide the crystalline orientation of the epilayer 240. The growth of the epilayer 240 then extends to cover the entire graphene layer 220, forming a planar epilayer 240 (e.g., FIG. 2F). In some embodiments, an epitaxial material is grown on the patterned graphene for a short enough duration that portions (e.g., islands) of the epitaxial material do not merge with one another and a patterned epitaxial material 240 (e.g., comprising islands) results (e.g., 240 of FIG. 2E). Further growth of the epitaxial material 240 can then extend to cover the entire graphene layer 220, forming a planar epitaxial layer (also referred to herein as an epilayer) 240 (e.g., FIG. 2F).

In FIG. 2G, the formed epilayer 240 is released from the graphene layer 220 and the substrate 210. The released epilayer 240 is transferred to a target substrate 250, as shown in FIG. 2H, for further processing, such as forming a functional device. The graphene layer 220 and the substrate 210, after the release of the epilayer 240 shown in FIG. 2G, is then reused to fabricate another epilayer, and the cycle can be repeated multiple times.

The method 200 uses graphene for layer transfer for illustrative purposes. In practice, the graphene layer 220 can be replaced by any other 2D layer described herein.

U.S. Provisional Application No. 62/585,954, filed Nov. 14, 2017 and entitled “EPITAXIAL GROWTH AND TRANSFER VIA PATTERNED TWO-DIMENSIONAL (2D) LAYERS,” is incorporated herein by reference in its entirety for all purposes.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments can be implemented in any of numerous ways. For example, embodiments of designing and making the technology disclosed herein may be implemented using hardware, software or a combination thereof. When implemented in software, the software code can be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer. Additionally, a computer may be embedded in a device not generally regarded as a computer but with suitable processing capabilities, including a Personal Digital Assistant (PDA), a smart phone or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes (outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the invention discussed above. The computer readable medium or media can be transportable, such that the program or programs stored thereon can be loaded onto one or more different computers or other processors to implement various aspects of the present invention as discussed above.

The terms “program” or “software” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present invention need not reside on a single computer or processor, but may be distributed in a modular fashion amongst a number of different computers or processors to implement various aspects of the present invention.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method of manufacturing a semiconductor device, the method comprising:
growing a two-dimensional (2D) layer comprising a 2D material on a first substrate;
forming a plurality of holes in the 2D layer to create a patterned 2D layer;
forming a single-crystalline film on the patterned 2D layer; and
transferring the single-crystalline film onto a second substrate.

2. The method of claim 1, wherein the 2D material comprises graphene.

3. The method of claim 1, wherein the first substrate comprises silicon.

4. (canceled)

5. The method of claim 1, wherein forming the plurality of holes comprises:
forming a metal mask on the 2D layer, the metal mask comprising a plurality of metal islands disposed on the 2D layer;
etching the 2D layer to form the plurality of holes; and
removing the metal mask from the 2D layer.

6. The method of claim 5, wherein etching the 2D layer comprises etching the 2D layer using an inert gas plasma.

7. The method of claim 1, further comprising:
growing the first substrate on a parent substrate via epitaxial growth.

8. The method of claim 7, wherein the parent substrate comprises GaN and the first substrate comprises InGaN.

9. The method of claim 7, wherein the parent substrate comprises GaAs and the first substrate comprises InGaP.

10. The method of claim 7, wherein the parent substrate comprises InP and the first substrate comprises InGaAs.

11. The method of claim 1, wherein the 2D material comprises MoS₂.

12. The method of claim 1, wherein the 2D material comprises WSe₂.

13. The method of claim 1, wherein the 2D material comprises Boron Nitride.

14. The method of claim 1, wherein the first substrate comprises germanium.

15. The method of claim 5, wherein etching the 2D layer comprises etching the 2D layer using an oxygen plasma.

16. The method of claim 1, further comprising:
growing the first substrate on a parent substrate via pseudomorphic growth.

17. The method of claim 1, wherein the single-crystalline film is epitaxially matched to the first substrate.

18. A method of manufacturing a semiconductor device, the method comprising:
forming a plurality of holes in a two-dimensional (2D) layer disposed on a first substrate to create a patterned 2D layer;
forming a single-crystalline film on the patterned 2D layer; and
separating the single-crystalline film and the first substrate.

19. The method of claim 18, wherein the single-crystalline film is epitaxially matched to the first substrate.

20. The method of claim 18, wherein the single-crystalline film and the substrate are made of the same material.

21. The method of claim 18, further comprising, after separating the single-crystalline film and the first substrate, forming a second single-crystalline film over the substrate.
